(19) United States
(12) Patent Application Publication
(10) Pub. No.: US 2023/0143672 A1
(43) Pub. Date: May 11, 2023

(54) MOLDED MICROFLUIDIC SUBSTRATE HAVING MICROFLUIDIC CHANNEL

(71) Applicant: Hewlett-Packard Development Company, L.P., Spring (US)

(72) Inventors: Chien-Hua Chen, Corvallis, OR (US); Michael W. Cumbie, Corvallis, OR (US); Michael G. Groh, Corvallis, OR (US)

(73) Assignee: Hewlett-Packard Development Company, L.P., Spring, TX (US)

(21) Appl. No.: 17/912,873

(22) PCT Filed: Apr. 10, 2020
(86) PCT No.: PCT/US2020/027597

§ 371 Date: Sep. 20, 2022

(51) Int. Cl. B01L 3/00

(52) U.S. Cl. CPC B01L 3/502707; B01L 3/502715

(57) ABSTRACT

A molded microfluidic substrate includes a molding compound layer. The molded microfluidic substrate includes a microfluidic channel. The microfluidic channel of the molded microfluidic substrate is formed within the molding compound layer of the molded microfluidic substrate. The microfluidic channel of the molded microfluidic substrate corresponds to a sacrificial metal bond wire.

### BACKGROUND

Microfluidic devices leverage the physical and chemical properties of liquids and gases at a small scale, such as at a sub-millimeter scale. Microfluidic devices geometrically constrain fluids to precisely control and manipulate the fluids for a wide variety of different applications. Such applications can include digital microfluidic (DMF) and DNA applications, as well as applications as varied as lab-on-a-chip, inkjet, electrophoresis, capacitance sensing, fluidic heat sink, and fluidic sensor probe applications, among other applications. A microfluidic device can include a microfluidic substrate in which a series of microfluidic channels are etched or molded.

### BRIEF DESCRIPTION OF THE DRAWINGS

FIG. 1 is a flowchart of an example method for making a molded microfluidic substrate having a microfluidic channel corresponding to a sacrificial metal bond wire.

FIGS. 2A, 2B, 2C, and 2D are cross-sectional diagrams of different example metal bond layers that can be used in the method of FIG. 1.

FIG. 3 is a diagram illustrating example performance of the method of FIG. 1 in which uncoated and coated sacrificial metal bond wire and ribbon as well as non-sacrificial metal bond wire and ribbon are attached to a metal bond layer.

FIG. 4 is a diagram illustrating example performance of the method of FIG. 1 in which a molding compound is applied to form a molding compound layer that encapsulates the uncoated and coated sacrificial metal bond wire and ribbon and the non-sacrificial metal bond wire and ribbon, after their attachment in FIG. 3.

FIG. 5 is a diagram illustrating example performance of the method of FIG. 1 in which a portion of the formed molding compound layer encapsulating the uncoated and coated sacrificial metal bond wire and ribbon and the non-sacrificial metal bond wire and ribbon is removed, after application of the molding compound in FIG. 4.

FIGS. 6A, 6B, and 6C are cross-sectional, top, and bottom diagrams of an example molded microfluidic substrate having a microfluidic channel corresponding to a sacrificial metal bond layer, which can be fabricated by example performance of the method of FIG. 1 in which the sacrificial metal is etched away, after removal of a portion of the molding compound layer in FIG. 5.

FIG. 7A is a cross-sectional diagram illustrating example masking of a non-sacrificial metal bond wire of the same metal as a sacrificial metal bond wire or ribbon prior to etching. FIG. 7B is a cross-sectional diagram of a portion of an example molded microfluidic substrate after removal of the mask of FIG. 7A.

FIG. 8 is a block diagram of an example molded microfluidic substrate having a microfluidic channel.

FIG. 9 is a diagram of an example electronic device having a molded microfluidic substrate with a microfluidic channel.

FIG. 10 is a flowchart of an example method for making a molded microfluidic substrate having a microfluidic channel.

### DETAILED DESCRIPTION

As noted in the background section, a microfluidic device can include a microfluidic substrate in which microfluidic channels are etched or molded. Different processes can be employed to fabricate microfluidic substrates having such channels. The different processes have competing tradeoffs as to, among other things, the types of microfluidic channels that can be formed, as well as the overall cost of substrate fabrication. In general, relatively complex microfluidic substrates having three-dimensional (3D) microfluidic channels are costly to manufacture, making microfluidic devices more expensive and therefore not employed as widely as may be desired.

For example, injection-molded cyclic olefin copolymer (COC) microfluidic substrates can be manufactured inexpensively, but are generally limited to formation of two-dimensional (2D) microfluidic channels. Fabricating microfluidic substrates by instead using photolithographic deposition and etching processes permits formation of 3D microfluidic channels, but such processes are much more expensive. Fabricating microfluidic substrates by molded interconnect substrate (MIS) processes also permits formation of 3D channels, and while such processes are less expensive than pure photolithographic techniques, they are still relatively expensive.

Techniques described herein provide for a molded microfluidic substrate having a microfluidic channel corresponding to an etched-away sacrificial bond wire or ribbon. A sacrificial bond wire can be attached to a metal bond wire, and then bent in correspondence with a desired microfluidic channel to be formed. Molding compound can be applied to encase the sacrificial metal bond wire within a molding compound layer. After removal of a portion of the molding compound layer, the resultantly exposed sacrificial metal bond wire is etched away, yielding the microfluidic substrate having the desired microfluidic channel formed within the molding compound layer.

This novel molding process is much less expensive than the 3D-oriented approaches outlined above. Rather than depositing and etching sacrificial metal in layers using semiconductor-like photolithographic techniques, or forming sacrificial metal in layers using such photolithographic techniques followed by molding compound application as in MIS processes, the described molding process novelly leverages wire bonding processes normally used for integrated circuit (IC) packaging. Such wire bonding processes permit more cost effective 3D microfluidic channel definition. Once the sacrificial metal bond wires have been attached, they are encased in molding compound and ultimately etched away to innovatively yield a microfluidic substrate.

Furthermore, the described techniques can simply and cost effectively provide for molded microfluidic substrates having metal-plated or metal-coated microfluidic channels. Many metal bond wires used in IC packaging are coated with metal, such as palladium-coated copper (PCC) and silver (PCS) bond wires. The core metal can be selectively etched away, leaving the non-etched metal coating to encase the now-hollow cores within the molding compound layer, and thus realizing a microfluidic substrate having metal-coated microfluidic channels without having to perform any additional fabrication steps or acts, and so on. Instead, a coated as opposed to uncoated metal bond wire is attached, and the subsequent metal etching is selective to the core metal of the bond wire.

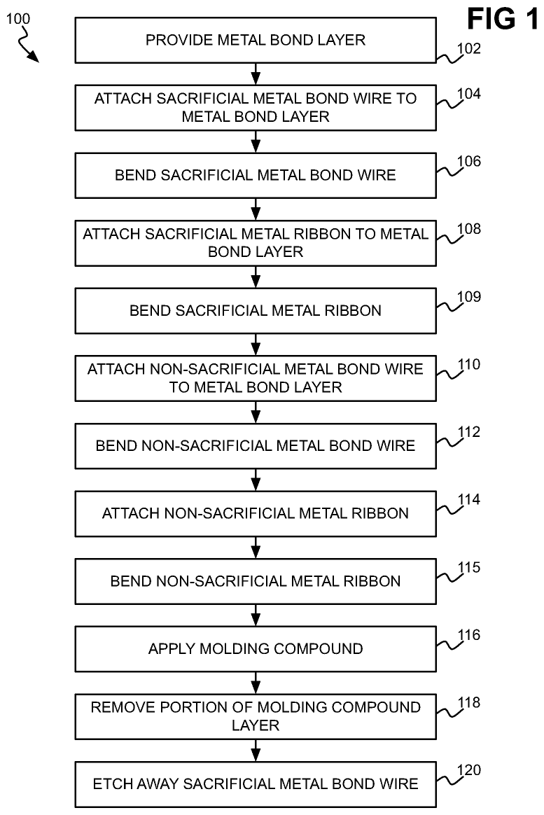

FIG. 1 shows an example method 100 for making a molded microfluidic substrate. The method 100 includes providing a metal bond layer (102). Providing the metal bond layer can include forming an MIS sacrificial metal bond layer having a sacrificial metal portion. Such an MIS sacrificial metal bond layer is formed using MIS techniques, in which sacrificial metal is selectively deposited via photolithographic processes and then molding compound is applied. The sacrificial metal may be copper, gold, aluminum, silver, or another type of metal. The molding compound may be epoxy molding compound (EMC).

Providing the metal bond layer can instead include providing a non-MIS sacrificial metal carrier, such as a copper, gold, aluminum, silver, or other type of metal carrier. Providing the metal bond layer can instead include providing a semiconductor die having non-sacrificial metal bond pads that act as the metal bond layer. Providing the metal bond layer can instead include providing a semiconductor package in which a semiconductor die has been disposed, and which has non-sacrificial metal contact pads that act as the metal bond layer. The metal bond layer may be provided in a different manner as well.

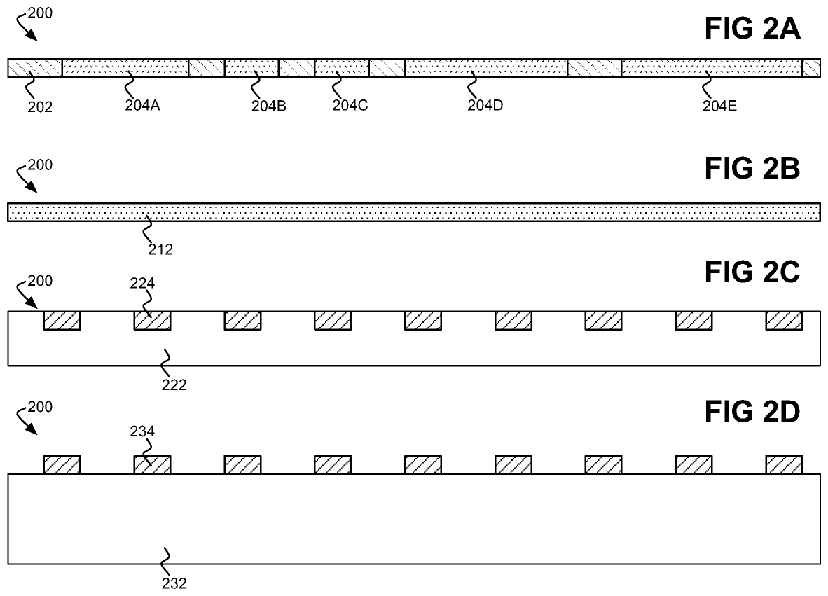

FIGS. 2A, 2B, 2C, and 2D show cross sections of different examples of a metal bond layer 200. In FIG. 2A, the metal bond layer 200 is an MIS sacrificial metal bond layer having molding compound 202 planarly surrounding sacrificial metal portions 204A, 204B, 204C, 204D, and 204E, which will be subsequently etched away, and which are collectively referred to as the sacrificial metal portions 204. Uncoated and coated sacrificial and non-sacrificial metal bond wire and ribbon can be subsequently attached to the sacrificial metal portions 204. The sacrificial metal portions 204 correspond to desired portions of microfluidic channels to be formed within the molded microfluidic substrate under manufacture.

In FIG. 2B, the metal bond layer 200 includes a non-MIS sacrificial metal carrier 212 that will be subsequently etched away and to which uncoated and coated sacrificial and non-sacrificial metal bond wire and ribbon can be subsequently attached. In FIG. 2C, a semiconductor die 222 has non-sacrificial metal bond pads 224 that act as the metal bond layer 200. In FIG. 2D, a semiconductor package 232 has non-sacrificial metal contact pads 234 that act as the metal bond layer 200. Uncoated and coated sacrificial and non-sacrificial metal bond wire and ribbon can be subsequently attached to the bond pads 224 and contact pads 234 of FIGS. 2C and 2D, respectively.

Referring back to FIG. 1, the method 100 includes attaching a sacrificial metal bond wire to the provided metal bond layer (104). The method 100 further includes bending the sacrificial metal bond wire in correspondence with a desired microfluidic channel to be formed within the molded microfluidic substrate under manufacture (106). The sacrificial metal bond wire may be uncoated sacrificial metal bond wire, such as uncoated copper, gold, aluminum, silver, or other uncoated metal bond wire.

The sacrificial metal bond wire may be a coated sacrificial metal bond wire, in which a sacrificial metal core is surrounded by an outer non-sacrificial metal surface. The sacrificial metal core may be copper, gold, aluminum, silver, or another metal. The non-sacrificial metal outer-metal coated surface may be palladium, silver (if the sacrificial metal core is not silver), or another metal that is different than the sacrificial metal core.

Attachment and subsequent bending of the sacrificial metal bond wire can be performed using metal wire bonding processes that are normally used for IC packaging. Such wire bonding processes are normally used to make interconnections between an IC or other semiconductor device and its packaging during semiconductor device fabrication. Such processes are also less commonly used to connect an IC to other electronics or to connect from one printed circuit board (PCB) to another.

The method 100 can include attaching a sacrificial metal ribbon to the metal bond layer (108), and may include bending the sacrificial metal ribbon (109). The sacrificial metal ribbon, as may be bent, corresponding to a desired microfluidic channel to be formed within the molded microfluidic substrate under manufacture. The sacrificial metal ribbon can be of the same sacrificial metal as the attached sacrificial metal bond wire. Whereas the sacrificial metal bond wire is generally round in cross-sectional shape, the sacrificial metal ribbon is generally rectangularly flat in cross-sectional shape.

The method 100 can include attaching a non-sacrificial metal bond wire to the metal bond layer (110). The method 100 can include bending the non-sacrificial metal bond wire in correspondence with a desired metal component to be formed within the microfluidic substrate under manufacture (112). The method 100 can include attaching a non-sacrificial metal ribbon (114), and may include bending the non-sacrificial metal ribbon (115). The non-sacrificial metal ribbon, as may be bent, corresponds to a desired metal component to be formed within the substrate under manufacture.

The non-sacrificial metal bond wire and ribbon may be palladium, silver (if the sacrificial metal bond wire is not silver), or another metal that is different than the sacrificial metal bond wire. The metal component to be formed by the non-sacrificial metal bond wire may be a conductive interconnect or other type of metal component. The metal component to be formed by the non-sacrificial metal ribbon may be a heat sink, conductive or capacitive plate, or other type of metal component.

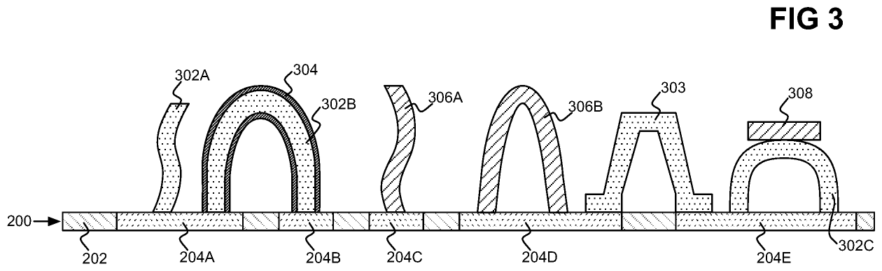

FIG. 3 shows example performance of parts 104, 106, 108, 110, 112, and 114 of the method 100 after part 102 has already been performed. In the example of FIG. 3, the metal bond layer 200 is the MIS sacrificial metal bond layer of FIG. 2A, which includes molding compound 202 planarly surrounding sacrificial metal portions 204. FIG. 3 shows sacrificial metal bond wires 302A, 302B, and 302C, collectively referred to as the sacrificial metal bond wires 302; a sacrificial metal ribbon 303; non-sacrificial metal bond wires 306A and 306B, collectively referred to as the non-sacrificial metal bond wires 306; and a non-sacrificial metal ribbon 308.

The sacrificial metal bond wire 302A is uncoated, and can be of the same sacrificial metal as the sacrificial metal portions 204 of the metal bond layer 200. One end of the sacrificial metal bond wire 302A is attached to the sacrificial metal portion 204A. The bond wire 302A is then bent in correspondence with a desired microfluidic channel to be formed within the microfluidic substrate under manufacture.

The sacrificial metal bond wire 302B is coated with a non-sacrificial metal coating 304. The core metal of the bond wire 302B can be of the same sacrificial metal as the sacrificial metal portions 204 of the metal bond layer 200, whereas the non-sacrificial metal coating 304 is of a different metal. One end of the bond wire 302B is attached to the sacrificial metal portion 204A and bent in correspondence with a desired microfluidic channel to be formed within the microfluidic substrate under manufacture, prior to attachment of the other end of the wire 302B to the sacrificial metal portion 204B.

The sacrificial metal bond wire 302C is uncoated, and can be of the same sacrificial metal as the sacrificial metal portions 204 of the metal bond layer 200. One end of the bond wire 302C is attached to the sacrificial metal portion 204E, and is bent in correspondence with a desired microfluidic channel to be formed within the microfluidic substrate under manufacture. The other end of the bond wire 302B is then attached to the same sacrificial metal portion 204E.

The sacrificial metal ribbon 303 is uncoated, and can be of the same sacrificial metal as the sacrificial metal portions 204 of the metal bond layer 200. One end of the ribbon 303 is attached the sacrificial metal portion 204D, and is bent in correspondence with a desired microfluidic channel to be formed within the microfluidic substrate under manufacture. The other end of the ribbon 303 is then attached to the sacrificial metal portion 204E.

The non-sacrificial metal bond wire 306A is uncoated, and is of a different metal than the sacrificial metal portions 204 of the metal bond layer 200. The bond wire 306A may be of the same metal as the non-sacrificial metal coating 304 of the sacrificial metal bond wire 302B. One end of the bond wire 306A is attached to the sacrificial metal portion 204C, and is then bent in correspondence with a desired metal component to be formed within the microfluidic substrate under manufacture.

The non-sacrificial metal bond wire 306B is also uncoated, and is of a different metal than the sacrificial metal portions 204 of the metal bond layer 200. The bond wire 306B may be of the same metal as the non-sacrificial metal coating 304 of the sacrificial metal bond wire 302B, and/or of the same metal as the non-sacrificial metal bond wire 306A. One end of the bond wire 306B is attached to the sacrificial metal portion 204D, and is bent in correspondence with a desired metal component to be formed within the microfluidic substrate under manufacture, prior to attachment of the other end of the bond wire 306B to the same sacrificial metal portion 204D.

The non-sacrificial metal ribbon 308 is uncoated, and is of a different metal than the sacrificial metal portions 204 of the metal bond layer 200. The ribbon 308 may be of the same metal as the non-sacrificial metal coating 304 of the sacrificial metal bond wire 302B, and/or of the same metal as the non-sacrificial metal bond wires 306. The ribbon 308 is attached to the sacrificial metal bond wire 302C that is bent and attached to the sacrificial metal portion 204E. The ribbon 308 corresponds to a desired metal component to be formed within the microfluidic substrate under manufacture.

FIG. 3 thus shows where and which ends of the bond wires 302 and 306 and the ribbons 303 and 308 are each attached can vary. As to the sacrificial metal bond wire 302 and ribbon 303, such variation in attachment, as well as variation in bending, is governed by the microfluidic channels that are desired to be formed within the molded microfluidic substrate under manufacture. As to the non-sacrificial metal bond wire 306 and ribbon 308, such variation in attachment, as well as variation in bending, is governed by the metal components that are desired to be formed within the microfluidic substrate under manufacture.

Referring back to FIG. 1, the method 100 includes applying molding compound (116), such as EMC. Application of molding compound encapsulates the sacrificial metal bond wire and ribbon and the non-sacrificial bond wire and ribbon within a molding compound layer, such that there are no air gaps within the layer. The molding compound can be applied in a manner similar to its application in an MIS process, with a difference being that the molding compound is applied around bond wire and ribbon in a single application or layer, as opposed to around photolithographically defined metal in multiple applications as such metal layers are formed.

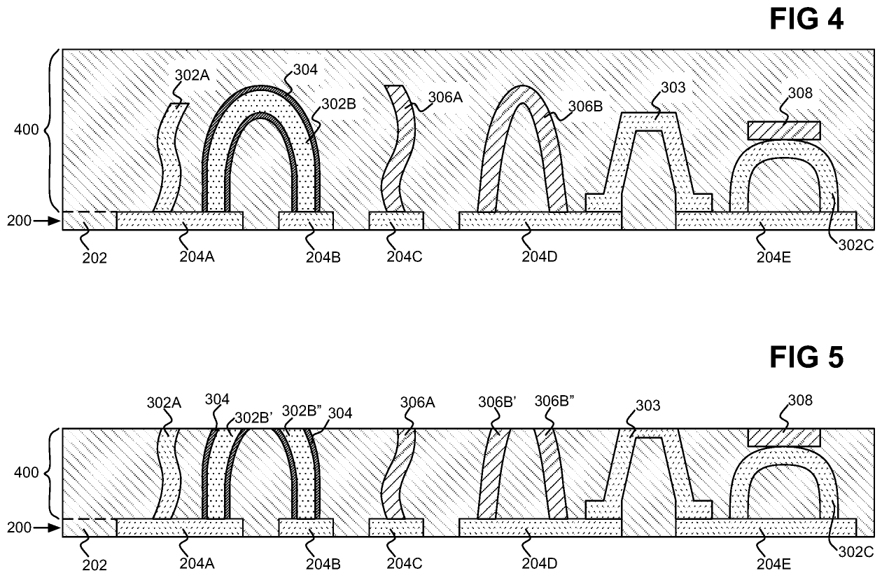

FIG. 4 shows example performance of part 116 of the method 100 after parts 104, 106, 108, 110, 112, and 114 have already been performed. The example of FIG. 4 includes the sacrificial metal bond wires 302 and ribbon 303 and the non-sacrificial metal bond wires 306 and ribbon 308 of FIG. 3. The same molding compound 202 of the metal bond layer 200 that also includes the sacrificial metal portions 204 is applied, encapsulating the bond wires 302 and 306 and the ribbons 303 and 308 within a molding compound layer 400. In the example of FIG. 4, none of the bond wires 302 and 306 and the ribbons 303 and 308 are exposed within the molding compound layer 400.

Referring back to FIG. 1, the method 100 includes removing a portion of the molding compound layer (118). Removal of a portion of the molding compound layer exposes some or all of the sacrificial metal bond wires and ribbons and the non-sacrificial metal bond wires and ribbons within the layer. The portion of the molding compound layer can be removed by shaving or grinding, among other molding compound layer portion removal techniques.

FIG. 5 shows example performance of part 118 of the method 100 after part 116 has already been performed. The example of FIG. 5 includes the sacrificial metal bond wires 302 and ribbon 303 and the non-sacrificial metal bond wires 306 and ribbon 308 encapsulated within the molding compound layer 400 of molding compound 202 atop the metal bond layer 200 that also includes molding compound 202 as well as the sacrificial metal portions 204. A top portion of the molding compound layer 400 is removed in FIG. 5, exposing a majority of the bond wires 302 and 306 and the ribbons 303 and 308.

The heights of the sacrificial metal bond wire 302A and the non-sacrificial metal bond wire 306A are reduced after removal of a portion of the molding compound layer 400. The coated sacrificial metal bond wire 302B has been divided into separate coated sacrificial metal bond wires 302B′ and 3026″; likewise, the non-sacrificial metal bond wire 306B has been divided into separate non-sacrificial metal bond wires 306B′ and 306B″. The horizontal top portions of the sacrificial metal ribbon 303 and the non-sacrificial ribbon 308 have been reduced in height. The sacrificial metal bond wire 302C remains encapsulated and not exposed within the molding compound layer 400, however.

Referring back to FIG. 1, the method 100 includes etching away the sacrificial metal bond wire (120). Any other sacrificial metal is likewise etched away, such as the sacrificial metal ribbon and any sacrificial metal of the metal bond layer on which the bond wire and ribbon have been attached. The etching is selective to the sacrificial metal. The non-sacrificial metal coating of any coated sacrificial bond wire remains, as does any non-sacrificial metal bond wire and ribbon. Etching away the sacrificial metal yields a molded microfluidic substrate having microfluidic channels formed within the molding compound layer and which correspond to the etched-away metal bond wire and ribbon.

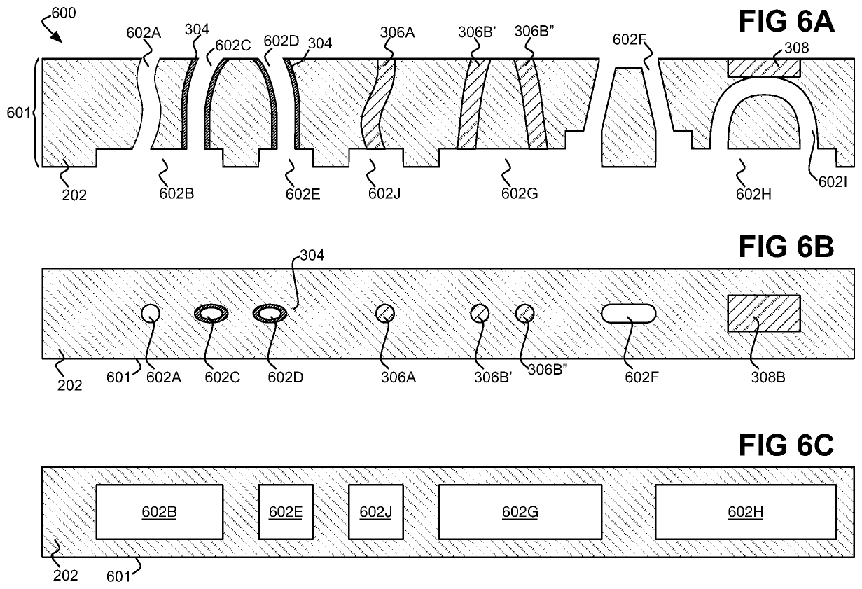

FIGS. 6A, 6B, and 6C respectively show cross-sectional, top, and bottom views of a molded microfluidic substrate 600 that performance of part 120 of the method 100 yields after part 118 has already been performed. The example of FIGS. 6A, 6B, and 6C includes microfluidic channel portions 602A, 602B, 602C, 602D, 602E, 602F, 602G, 602H, 602I, and 602J, which are collectively referred to as the microfluidic channel portions 602, within the molding compound layer 601 of molding compound 202. The example includes metal components corresponding to the non-sacrificial metal bond wires 306 and ribbon 308 within the molding compound layer 601.

The molding compound layer 601 encompasses the molding compound 202 of the metal bond layer 200 of FIG. 5 and the molding compound layer 400 of FIG. 5 in height. A microfluidic channel corresponding to the etched-away sacrificial metal bond wire 302A of FIG. 5 includes the microfluidic channel portion 602A remaining after the bond wire 302A has been etched away and the microfluidic channel portion 602B remaining after the sacrificial metal portion 204A of FIG. 5 has been etched away. The portion 204A has a round sidewall corresponding to the round profile of the etched-away bond wire 302A. The portion 602B is at the bottom exterior surface of the molding compound layer 601 and corresponds to the etched-away sacrificial metal portion 204A.

A microfluidic channel corresponding to the etched-away sacrificial metal bond wire 302B′ of FIG. 5 includes the microfluidic channel portion 602C remaining after the bond wire 302B′ has been etched away and the microfluidic channel portion 602B. The microfluidic channel portion 602C has a metal-plated sidewall corresponding to the non-sacrificial metal coating 304 that remains after the inner sacrificial metal core of the metal bond wire 302B′ has been etched away. The microfluidic channel portion 602C has a round sidewall corresponding to the round profile of the bond wire 302B′.

A microfluidic channel corresponding to the etched-away sacrificial metal bond wire 302B″ of FIG. 5 includes the microfluidic channel portion 602D remaining after the bond wire 302B″ has been etched away and the microfluidic channel portion 602E remaining after the sacrificial metal portion 204B of FIG. 5 has been etched away. The portion 602D has a metal-plated sidewall corresponding to the non-sacrificial metal coating 304 that remains after the inner sacrificial metal core of the metal bond wire 302B″ has been etched away. The portion 602D has a round sidewall corresponding to the round profile of the bond wire 302B″. The portion 602E is at the bottom exterior surface of the molding compound layer 601 and corresponds to the etched-away sacrificial metal portion 204B.

A microfluidic channel corresponding to the etched away sacrificial metal ribbon 303 of FIG. 5 includes the microfluidic channel portion 602F remaining after the ribbon 303 has been etched away, and the microfluidic channel portions 602G and 602H remaining after the sacrificial metal portions 204D and 204E of FIG. 5 have respectively been etched away. The microfluidic channel portions 602H and 602H are at the bottom exterior surface of the molding compound layer 601. The portions 602G and 602H respectively correspond to the etched-away sacrificial metal portions 204D and 204E.

A microfluidic channel corresponding to the etched-away sacrificial metal bond wire 302C of FIG. 5 includes the microfluidic channel portion 602I remaining after the bond wire 302C has been etched away and the microfluidic channel portion 602H remaining after the sacrificial metal portion 204E has respectively been etched away. Microfluidic channels within the molding compound layer 601 of the microfluidic substrate 600 thus correspond to the etched-away sacrificial metal bond wire 302 and ribbon 303. Each microfluidic channel includes multiple microfluidic channel portions 602 in the example of FIGS. 6A, 6B, and 6C. More generally, each microfluidic channel can include as few as one microfluidic channel portion 602.

A metal component of the molded microfluidic substrate 600 corresponds to and is formed by the non-sacrificial metal bond wire 306A that remains after etching and that is exposed at the microfluidic channel portion 602J. The microfluidic channel portion 602J remains after the sacrificial metal portion 204C of FIG. 5 has been etched away. The microfluidic channel portion 602J thus corresponds to the etched-away sacrificial metal portion 204C.

A metal component of the molded microfluidic substrate 600 corresponds to and is formed by the non-sacrificial metal bond wire 306B′ that remains after etching and that is exposed at the microfluidic channel portion 602G. A metal component corresponds to and is formed by the non-sacrificial metal bond wire 306B″ and that is also exposed at the portion 602G. Similarly, a metal component corresponds to and is formed by the non-sacrificial metal ribbon 308 that remains after etching and that is exposed at the microfluidic channel portion 602I.

In the examples that have been described, the non-sacrificial metal bond wire and ribbon are a different metal than the sacrificial metal bond wire and ribbon. However, in another implementation, the non-sacrificial metal bond wire and/or ribbon may be the same metal as the sacrificial metal bond wire and/or ribbon. In such instance, the non-sacrificial metal bond wire and/or ribbon in question is masked prior to etching away the sacrificial metal bond wire and ribbon so that the non-sacrificial metal bond wire and/or ribbon is not also etched away. The mask is removed after etching.

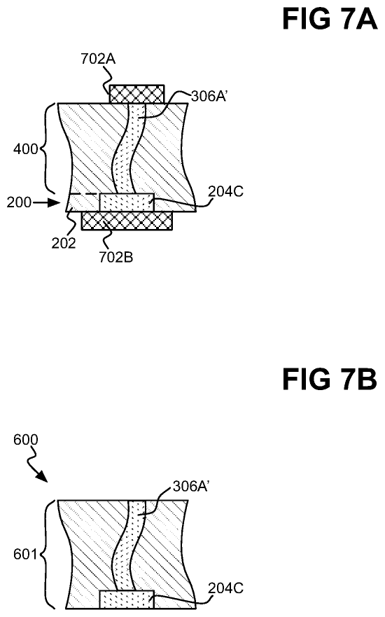

FIGS. 7A and 7B show an example of such an implementation in which the non-sacrificial metal bond wire and/or ribbon is of the same metal as the sacrificial metal bond wire and/or ribbon. FIG. 7A shows a masking layer 702A applied above the molding compound layer 400 to cover the non-sacrificial metal bond wire 306A′. FIG. 7A similarly shows a masking layer 702B applied below the metal bond layer 200 to cover the metal portion 204C.

The masking layers 702 can be applied after part 118 of the method 100 of FIG. 1 is performed, as shown in FIG. 5. Just a portion of the molding compound layer 400 and the metal bond layer 200 of FIG. 5 are shown in FIG. 7A. Furthermore, FIG. 7A differs from FIG. 5 in that FIG. 7 includes a non-sacrificial metal bond wire 306A′ of the same metal as the sacrificial metal bond wires 302, ribbon 303, and portions 204 of FIG. 5. By comparison, FIG. 5 includes a non-sacrificial metal bond wire 306A of a different metal than the sacrificial metal bond wires 302, ribbon 303, and portions 204.

FIG. 7B shows an example of the molded microfluidic substrate 600 that performance of part 120 of the method 100 of FIG. 1 yields after part 118 is performed and the masking layers 702 of FIG. 7A is then subsequently removed. The microfluidic substrate 600 of FIG. 7B is similar but not identical to the substrate 600 of FIG. 6. Just a portion of the substrate 600 of FIG. 6 is shown in FIG. 7B.

Specifically, FIG. 7B shows a metal component within the molding compound layer 601 which corresponds to and is formed by the non-sacrificial metal bond wire 306A′ and metal portion 204C. The bond wire 306A′ and metal portion 204C are not removed during etching due to their being masked by the masking layers 702 of FIG. 7A. By comparison, FIG. 6 shows a metal component corresponding to and formed by the non-sacrificial metal bond wire 306A, which is not removed during etching due to its being a different metal than the sacrificial metal bond wires 302, ribbon 303, and portions 204 of FIG. 5.

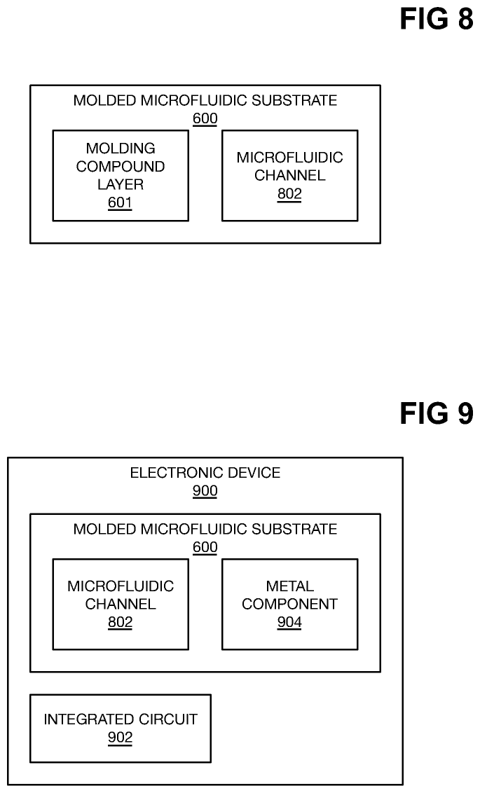

FIG. 8 shows a block diagram of the example molded microfluidic substrate 600. The molded microfluidic substrate 600 includes the molding compound layer 601 and a microfluidic channel 802 formed within the molding compound layer 601 and corresponding to a sacrificial metal bond wire. For example, the microfluidic channel 802 can correspond to any of the sacrificial metal bond wires 302 of FIGS. 3-5 that are etched away. The substrate 600 is a molded substrate in that it is formed via application of molding compound 202 to encapsulate the sacrificial metal bond wires 302 within the molding compound layer 400 in FIG. 4. The substrate 600 can be a 3D substrate in that, for instance, the sacrificial metal bond wire to which the channel 802 corresponds can be bent in all three spatial dimensions as desired.

FIG. 9 shows a block diagram of an electronic device 900, such as a microfluidic electronic device. The electronic device 900 includes the molded microfluidic substrate 600, which itself can include the microfluidic channel 802 and a metal component 904. The microfluidic channel 802 corresponds to a sacrificial metal bond wire or ribbon, such as any of the sacrificial metal bond wires 302 and ribbon 303 of FIGS. 3-5 that are etched away. The metal component 904 corresponds to a non-sacrificial metal bond wire or ribbon, such as any of the non-sacrificial metal bond wires 306 and ribbon 308 of FIGS. 3-5 and 7A-7B that are not etched away.

The electronic device 900 further includes an IC 902. The IC 902 may be in conductive contact with the metal component 904, in fluidic contact with the microfluidic channel 802, or in both conductive contact with the metal component 904 and fluidic contact with the microfluidic channel 802. The electronic device 900 can thus provide for electronic functionality to be performed by the IC 902 in relation to fluid routed through the molded microfluidic substrate 600. The electronic device 900 can in another implementation provide for active or passive cooling of the IC 902 via fluid routed through the molded microfluidic substrate 600.

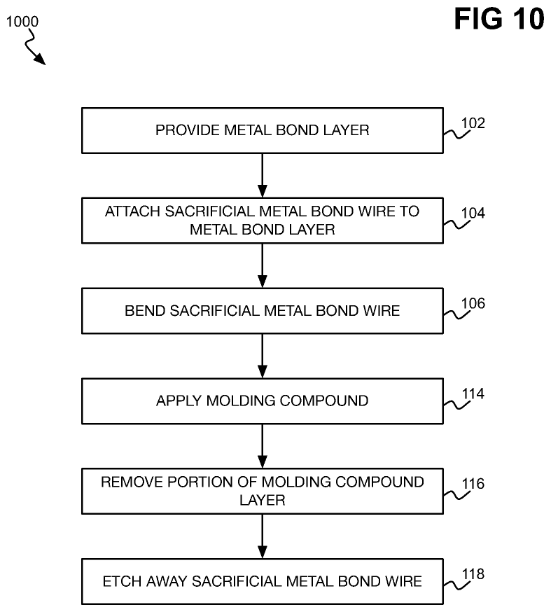

FIG. 10 shows an example method 1000 for making a molded microfluidic substrate having a microfluidic channel. The method 1000 is consistent with but more general than the method 100 of FIG. 1 that has been described. The method 1000 includes providing a metal bond layer (102), and attaching a sacrificial metal bond wire to the metal bond layer (104). The method 1000 includes bending the sacrificial metal bond wire in correspondence with a microfluidic channel to be formed (106).

The method 1000 includes applying a molding compound (114) to encase the sacrificial metal bond wire within a molding compound layer. The method 1000 includes then removing a portion of the molding compound layer (116) to expose the sacrificial metal bond wire within the molding compound layer. The method 1000 includes etching away the sacrificial metal bond wire (118) to yield a molded microfluidic substrate having the microfluidic channel formed within the molding compound layer and corresponding to the etched-away sacrificial metal bond wire.

Techniques have been described for making a molded microfluidic substrate having a microfluidic channel corresponding to a sacrificial bond wire. Such a molded microfluidic substrate can be less expensive to manufacture using the techniques described herein than 3D microfluidic substrates formed by other processes. The sidewall microfluidic channel can be coated with metal without the addition of further fabrication steps or acts, and so on.

1. A molded microfluidic substrate comprising:
a molding compound layer; and
a microfluidic channel formed within the molding compound layer and corresponding to a sacrificial metal bond wire.

2. The molded microfluidic substrate of claim 1, wherein the molding compound layer comprises an epoxy molding compound (EMC) layer.

3. The molded microfluidic substrate of claim 1, wherein the microfluidic channel has a round sidewall corresponding to a round profile of the sacrificial metal bond wire.

4. The molded microfluidic substrate of claim 1, wherein the microfluidic channel has a metal-plated sidewall, a non-sacrificial metal coating of the sacrificial metal bond wire forming the metal-plated sidewall.

5. The molded microfluidic substrate of claim 1, wherein the microfluidic channel has a portion at an exterior surface of the molding compound layer corresponding to an etched-way sacrificial metal portion of a molded-interconnect substrate (MIS) sacrificial metal bond layer.

6. The molded microfluidic substrate of claim 1, further comprising:
another microfluidic channel formed within the molding compound layer and corresponding to a sacrificial metal ribbon.

7. The molded microfluidic substrate of claim 1, further comprising:
a metal component formed by a non-sacrificial metal bond wire or ribbon within the molding compound layer.

8. The molded microfluidic substrate of claim 7, wherein the non-sacrificial metal bond wire or ribbon is a same metal as or a different metal than the sacrificial metal bond wire.

9. A method comprising:
providing a metal bond layer;
attaching a sacrificial metal bond wire to the metal bond layer;
bending the sacrificial metal bond wire in correspondence with a microfluidic channel to be formed;
applying a molding compound, encasing the sacrificial metal bond wire within a molding compound layer;
removing a portion of the molding compound layer, exposing the sacrificial metal bond wire within the molding compound layer; and
etching away the sacrificial metal bond wire, yielding a molded microfluidic substrate having the microfluidic channel formed within the molding compound layer and corresponding to the etched-away sacrificial metal bond wire.

10. The method of claim 9, wherein providing the metal bond layer comprises:
providing a non-molded-interconnect substrate (non-MIS) sacrificial metal carrier to which the sacrificial metal bond wire is subsequently attached and that is subsequently etched away with the sacrificial metal bond wire, a semiconductor die having a plurality of bond pads acting as the metal bond layer, or a semiconductor package having a plurality of contact pads acting as the metal bond layer.

11. The method of claim 9, wherein providing the metal bond layer comprises:
forming a molded-interconnect substrate (MIS) sacrificial metal bond layer having a sacrificial metal portion to which the sacrificial metal bond wire is subsequently attached and that is subsequently etched away with the sacrificial metal bond wire, yielding a portion of the microfluidic channel corresponding to the etched-away sacrificial metal portion of the MIS sacrificial metal bond layer.

12. The method of claim 9, wherein the sacrificial metal bond wire has a non-sacrificial metal coating that remains after etching, forming a metal-plated sidewall of the microfluidic channel.

13. The method of claim 9, further comprising:
attaching a sacrificial metal ribbon to the metal bond layer, the sacrificial metal ribbon subsequently etched away with the sacrificial metal bond wire, yielding another microfluidic channel of the molded microfluidic substrate formed within the molding compound layer and corresponding to the etched-away sacrificial metal ribbon.

14. The method of claim 9, further comprising:
attaching a non-sacrificial metal bond wire or ribbon,
wherein the non-sacrificial metal bond wire or ribbon is encased within the molding compound layer after application of the molding compound, remains after etching, and is exposed during removal of the portion of the molding compound layer, forming a metal component of the molded microfluidic substrate.

15. An electronic device comprising:
a molded microfluidic substrate having a microfluidic channel corresponding to a sacrificial metal bond wire or ribbon, and a metal component corresponding to a non-sacrificial metal bond wire or ribbon; and
an integrated circuit in conductive contact with the metal component, in fluidic contact with the microfluidic channel, or in conductive contact with the metal component and in fluidic contact with the microfluidic channel.
